(19) United States
(12) Patent Application Publication
(10) Pub. No.: US 2026/0101665 A1
(43) Pub. Date: Apr. 9, 2026

(54) COVER WINDOW ETCHING DEVICE FOR ELECTRONIC DEVICE AND COVER WINDOW ETCHING METHOD FOR ELECTRONIC DEVICE USING THE SAME

(71) Applicant: Samsung Display Co., Ltd., Yongin-si (KR)

(72) Inventors: BYEONG-BEOM KIM, Yongin-si (KR); SEUNGHO KIM, Yongin-si (KR); Jinsu NAM, Yongin-si (KR); JAEGIL LEE, Yongin-si (KR); MIN-HOON CHOI, Yongin-si (KR)

(21) Appl. No.: 19/225,196

(22) Filed: Jun. 2, 2025

(30) Foreign Application Priority Data
Oct. 8, 2024 (KR) 10-2024-0137065

(51) Int. Cl. H10K 71/00

(52) U.S. Cl. CPC H10K 71/00

(57) ABSTRACT

A cover window etching device for manufacturing an electronic device includes a stage on which a preliminary cover window is disposed, a plurality of plates disposed above the stage, and a nozzle disposed above the plates, where the nozzle sprays an etchant toward the preliminary cover window. The plates reciprocates in a first direction.

This application claims priority to Korean Patent Application No. 10-2024-0137065, filed on Oct. 8, 2024, and all the benefits accruing therefrom under 35 U.S.C. § 119, the content of which in its entirety is herein incorporated by reference.

### BACKGROUND

### (1) Field

The present disclosure herein relates to a cover window etching device for manufacturing an electronic device, and a cover window etching method for manufacturing an electronic device using the cover window etching device.

(2) Description of the Related Art

An electronic device may provide information to users by displaying various images on a display screen. Generally, the electronic device displays information within an allocated screen. Recently, flexible display devices including a foldable flexible display panel have been developed. Unlike a rigid electronic device, a flexible electronic device may be foldable, rollable, or bendable. Flexible electronic devices deformable into various shapes may be portable regardless of an existing display screen size, thereby improving user convenience.

Such an electronic device may include a display panel, and a cover window disposed on the display panel to protect the display panel.

### SUMMARY

The present disclosure provides a cover window etching device for manufacturing an electronic device capable of easily etching a cover window for an electronic device.

The present disclosure also provides a cover window etching device for manufacturing an electronic device which effectively prevents boundaries between a folding part and non-folding parts of the cover window for the electronic device from being viewed.

An embodiment of the invention provides a cover window etching device for manufacturing an electronic device including: a stage on which a preliminary cover window is disposed; a plurality of plates disposed above the stage; and a nozzle disposed above the plates, where the nozzle sprays an etchant toward the preliminary cover window, and the plates reciprocate in a first direction.

In an embodiment of the invention, a cover window etching method for manufacturing an electronic device includes: disposing a preliminary cover window on a stage; moving the stage to be disposed below a plurality of plates spaced apart from each other in a first direction inside an accommodation groove defined by a housing; and etching the preliminary cover window by spraying an etchant toward the preliminary cover window by using a nozzle disposed above the plates, where when the nozzle sprays the etchant, the plates move in the first direction.

In an embodiment of the invention, a cover window etching device for manufacturing an electronic device includes: a plurality of holding parts spaced apart from each other in a first direction, where the holding parts support a preliminary cover window; a source part disposed below the holding parts; and a housing which accommodates the holding parts and the source part, where the holding parts reciprocate in the first direction.

### BRIEF DESCRIPTION OF THE DRAWINGS

The above and other features of embodiments of the invention will become more apparent by describing in further detail embodiments thereof with reference to the accompanying drawings, in which:

FIG. 1 is a cross-sectional view of a cover window etching device for manufacturing an electronic device according to an embodiment of the invention;

FIG. 2A is a perspective view of a display device including a cover window manufactured by using the cover window etching device illustrated in FIG. 1;

FIG. 2B is a view illustrating the display device illustrated in FIG. 2A in a folded state;

FIG. 3 is an exploded perspective view of an electronic device illustrated in FIG. 2A;

FIG. 4 is a cross-sectional view of the cover window illustrated in FIG. 3;

FIGS. 5A to 5C are cross-sectional views for describing a method for etching the cover window illustrated in FIG. 4;

FIG. 6 is a cross-sectional view of a cover window etching device for manufacturing an electronic device according to an embodiment of the invention;

FIG. 7 is a cross-sectional view of a cover window etching device for manufacturing an electronic device according to an embodiment of the invention;

FIGS. 8A to 8C are views describing a method for etching a cover window by using the cover window etching device for manufacturing the electronic device illustrated in FIG. 6; and

FIG. 9 is a view describing a method for etching a cover window by using the cover window etching device for manufacturing the electronic device illustrated in FIG. 7.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In this specification, it will be understood that when an element (or a region, a layer, a portion, or the like) is referred to as being “connected to” or “coupled to” another element, it may be directly connected to or coupled to the other element, or other elements may be disposed therebetween.

Like reference numerals or symbols refer to like elements throughout. Also, in the drawings, the thickness, ratio, and size of the elements are exaggerated for effectively describing the technical contents.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or. ” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention are described with reference to the drawings.

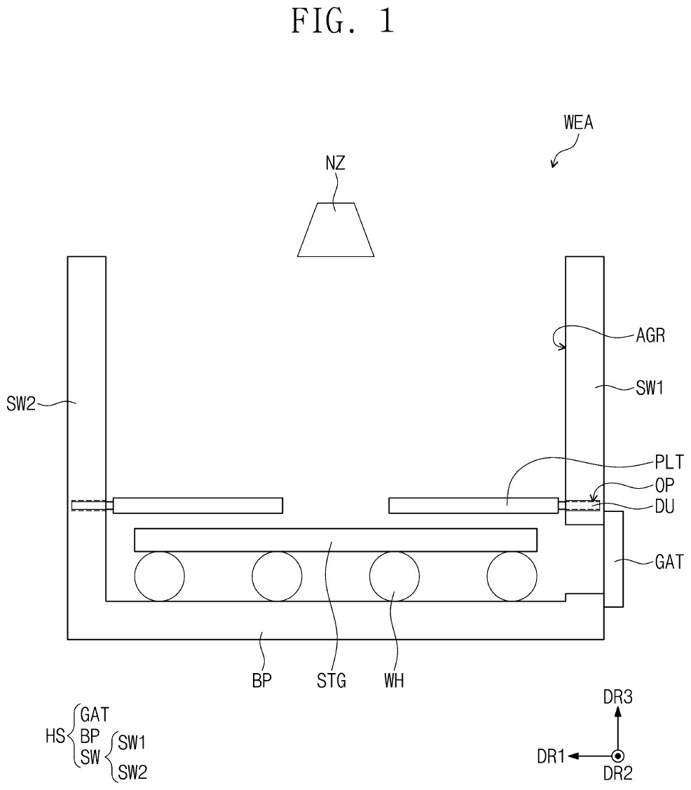

FIG. 1 is a cross-sectional view of a cover window etching device for manufacturing an electronic device according to an embodiment of the invention.

An embodiment of a cover window etching device WEA for manufacturing an electronic device may include a housing HS, a stage STG, a plurality of conveying parts WH, a plurality of plates PLT, a plurality of driving parts DU, and a nozzle NZ.

In an embodiment where the housing HS has a shape defined as a part of a quadrilateral is illustrated, but a shape of the housing HS is not limited thereto, and the shape of the housing HS may diversely change according to an embodiment. The housing HS may define an accommodation groove AGR which accommodates the stage STG, the conveying parts WH, and the plates PLT.

The housing HS may include a floor (or base) portion BP, a plurality of side wall portions SW, and a gate GAT. The floor portion BP (e.g., an upper surface thereof) may define a floor surface of the accommodation groove AGR. The side wall portions SW may extend upward from both opposing sides of the floor portion BP, which are opposed to each other in a first direction DR1. The side wall portions SW may be spaced apart from each other in the first direction DR1.

Hereinafter, a direction crossing the first direction DR1 is defined as a second direction DR2. A direction substantially perpendicular to a plane defined by the first and second directions DR1 and DR2 is defined as a third direction DR3. In this specification, the wording “when viewed in a plan view” may represent a state when viewed in the third direction DR3.

For example, FIG. 1 illustrates a cross-sectional view of the cover window etching device WEA when viewed in the second direction DR2.

The side wall portions SW may include a first side wall portion SW1 and a second side wall portion SW2. The first side wall portion SW1 may be defined as the side wall portion SW extending in the third direction DR3 from one side of the both opposing sides of the floor portion BP, which are opposed to each other in the first direction DR1. The second side wall portion SW2 may be defined as the side wall portion SW extending from the other side of the both opposing sides of the floor portion BP, which are opposed to each other in the first direction DR1. The first side wall portion SW1 and the second side wall portion SW2 may be spaced apart from each other in the first direction DR1.

Although not illustrated, a plurality of side wall portions SW may be further disposed on other opposing sides of the floor portion BP, which are opposed to each other in the second direction DR2.

A plurality of openings OP may be defined on the first side wall portion SW1 and the second side wall portion SW2. The openings OP may extend in the first direction DR1 from one side (i.e., inner side) toward another side (i.e., an outer side) of each of the first side wall portion SW1 and the second side wall portion SW2.

The gate GAT may cover the accommodation groove AGR and be disposed on an outer wall (or external surface) of the first side wall portion SW1. The stage STG may be conveyed into or out of the accommodation groove AGR by controlling an opening operation and a closing operation of the gate GAT.

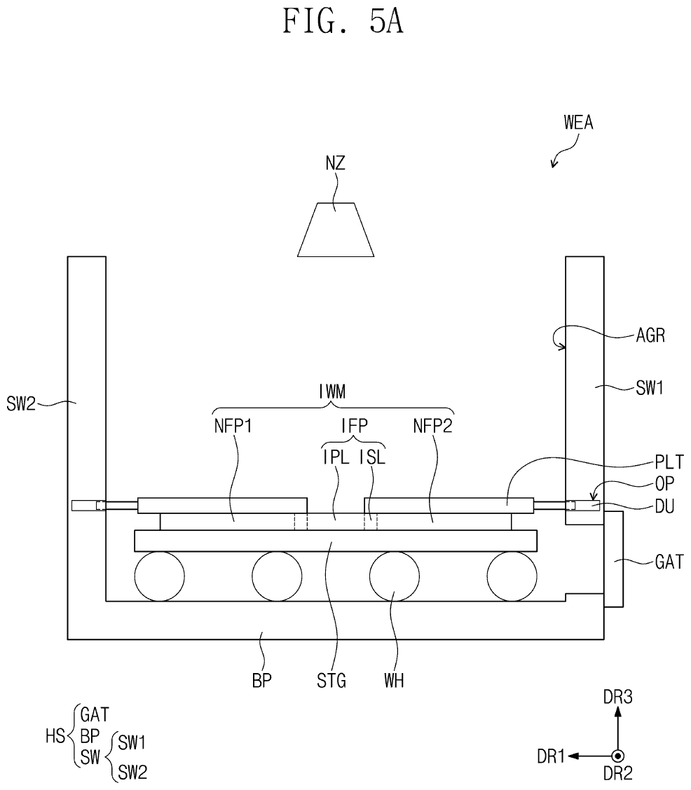

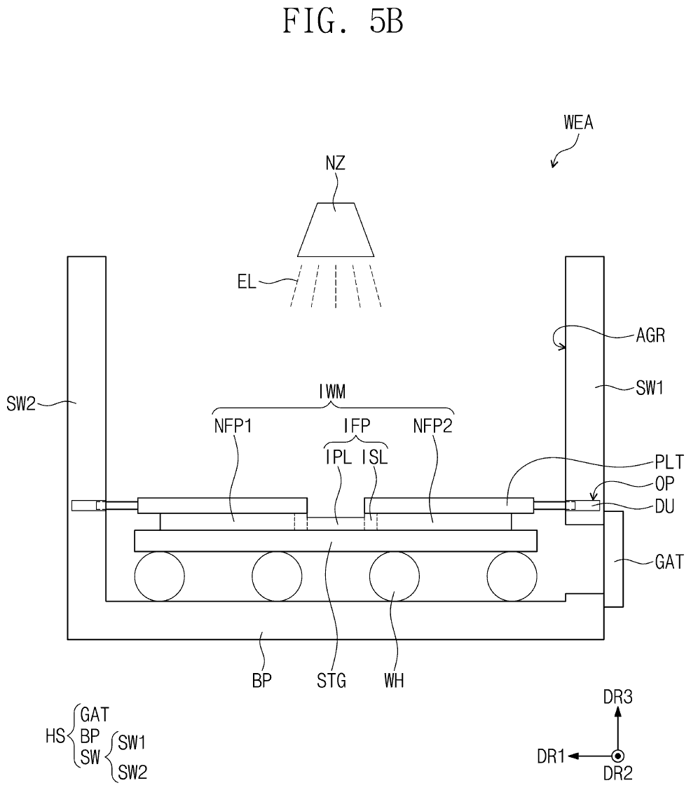

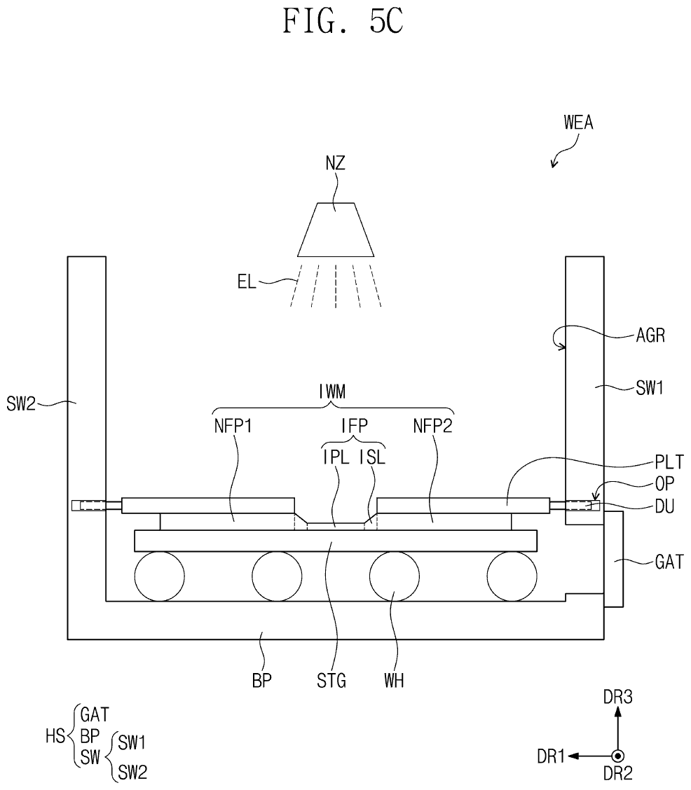

The stage STG may be disposed in the accommodation groove AGR. A preliminary cover window IWM (see FIG. 5A) to be described later may be disposed on the stage STG. Although not illustrated, an upper surface of the stage STG may be parallel to a plane defined by the first direction DR1 and the second direction DR2. Also, when the preliminary cover window IWM (see FIG. 5A) is disposed on the upper surface of the stage STG, a plurality of suction holes defined in the upper surface of the stage STG may be converted into a vacuum state and fix the preliminary cover window IWM (see FIG. 5A) on the upper surface of the stage STG.

The conveying parts WH may be disposed on a lower surface of the stage STG. In an embodiment, the conveying parts WH may be defined as a plurality of wheels as illustrated in FIG. 1, but an embodiment of the invention is not limited thereto. The conveying parts WH may include endless tracks, rails, linear motion guides, etc.

When the gate GAT performs opening operation, the stage STG and the preliminary cover window IWM (see FIG. 5A) may be conveyed into the accommodation groove AGR via the conveying parts WH.

The driving parts DU may be disposed on inner sides of each of the first side wall portion SW1 and the second side wall portion SW2 facing each other. A portion of each of the driving parts DU may be disposed in the openings OP.

The driving parts DU may reciprocate in the first direction DR1 when receiving an external signal. As the driving parts DU reciprocate in the first direction DR1, the driving parts DU may move into or out of the openings OP. The portions of the driving parts DU disposed inside the openings OP may have variable lengths.

The plates PLT may be disposed on the stage STG. The plates PLT may be spaced apart from each other above the stage STG in the first direction DR1. The plates PLT may overlap both opposing sides of the stage STG, which are opposed to each other in the first direction DR1.

Outer sides of the plates PLT, which are respectively opposed to the inner sides of the plates PLT and opposed to each other in the first direction DR1, may be connected to the driving parts DU. Accordingly, when the driving parts DU reciprocate in the first direction DR1, the plates PLT may reciprocate in the first direction DR1.

The nozzle NZ may be disposed above the stage STG and the plates PLT. The nozzle NZ may spray an etchant EL to be described later (see FIG. 5B).

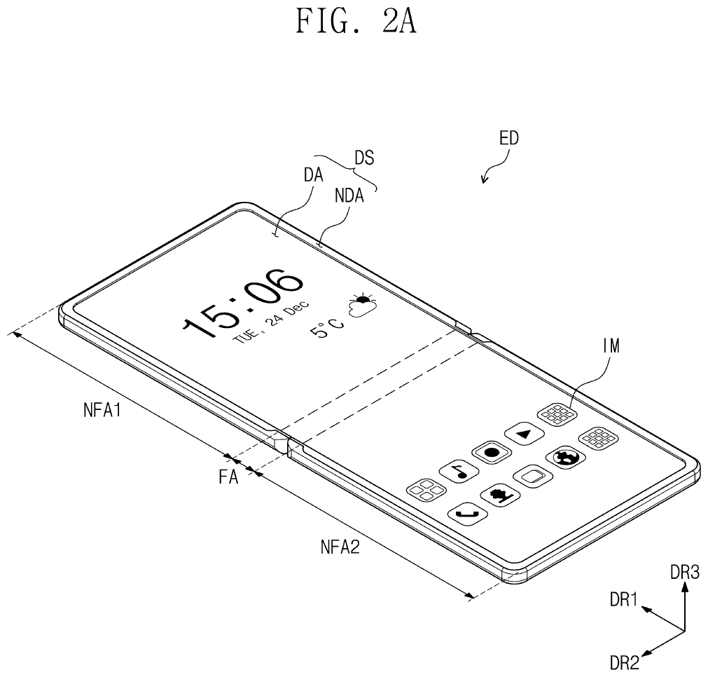

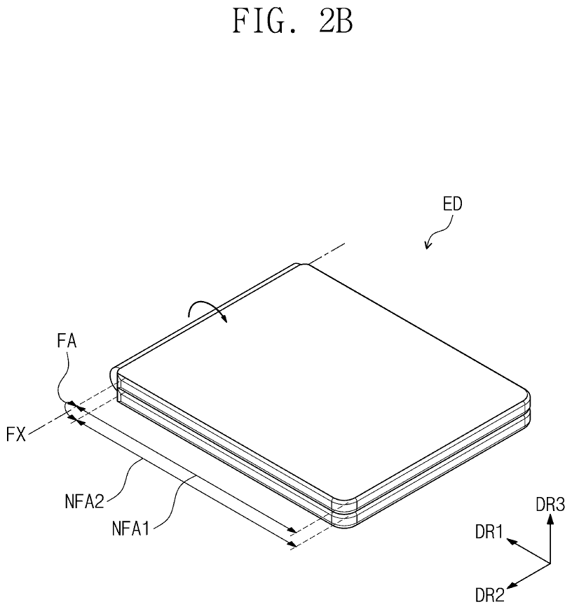

FIG. 2A is a perspective view of a display device including a cover window manufactured by using the cover window etching device illustrated in FIG. 1. FIG. 2B is a view illustrating the display device illustrated in FIG. 2A in a folded state.

Referring to FIG. 2A, an embodiment of an electronic device ED may have a rectangular shape that has the long sides extending in the first direction DR1 and the short sides extending in the second direction DR2 in a plan view (or when viewed in the third direction DR3). However, an embodiment of the invention is not limited thereto, and the electronic device ED may have various shapes, such as a circular or polygonal shape in a plan view. The electronic device ED may be a flexible electronic device.

The electronic device ED may include a folding region FA and a plurality of non-folding regions NFA1 and NFA2. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged in the first direction DR1.

An embodiment where a single folding region FA and two non-folding regions NFA1 and NFA2 are defined is illustrated in FIG. 2A as an example, but the number of the folding region FA and the number of the non-folding regions NFA1 and NFA2 are not limited thereto. In an embodiment, for example, the electronic device ED may include more than two non-folding regions and a plurality of folding regions disposed with the non-folding regions between the folding regions.

An upper surface of the electronic device ED may be defined as a display surface DS and have a flat surface defined by the first direction DR1 and the second direction DR2. Images IM generated from the electronic device ED may be provided to users through the display surface DS.

The display surface DS may include a display region DA and a non-display region NDA around the display region DA. The display region DA may display images, and the non-display region NDA may not display images. The non-display region NDA may surround the display region DA and define a border of the electronic device ED printed in a predetermined color.

Although not illustrated, the electronic device ED may include a plurality of sensors and at least one camera.

Referring to FIG. 2B, the electronic device ED may be a foldable electronic device ED which is folded or unfolded. In an embodiment, for example, the electronic device ED may be folded in a way such that the folding region FA is bent with respect to a folding axis FX parallel to the second direction DR2. The folding axis FX may be defined as a short axis parallel to a short side of the electronic device ED.

When the electronic device ED is folded, the electronic device ED may be in-folded such that the first non-folding region NFA1 and the second non-folding region NFA2 face each other and the display surface DS is not exposed to the outside. However, the embodiment of the invention is not limited thereto. In an embodiment, for example, the electronic device ED may also be out-folded with respect to the folding axis FX such that the display surface DS is exposed to the outside.

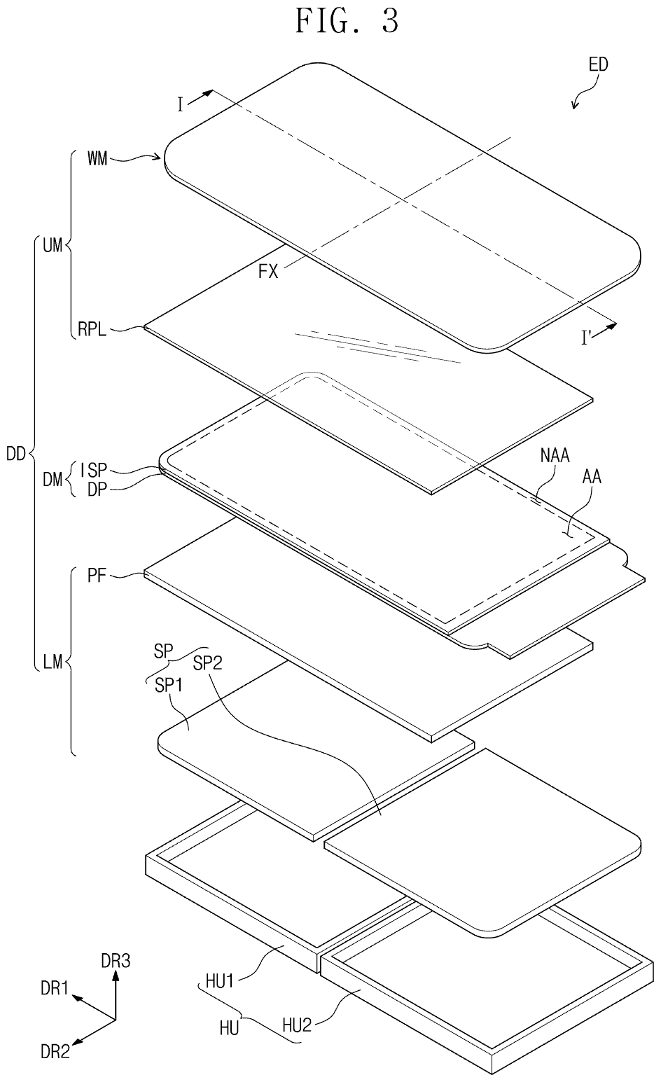

FIG. 3 is an exploded perspective view of the electronic device illustrated in FIG. 2A.

Referring to FIG. 3, an embodiment of an electronic device ED includes a display device DD and a case HU. Although not illustrated, the electronic device ED may further include a mechanical structure for controlling a folding operation of the display device DD.

The display device DD according to an embodiment of the invention may include a display module DM which displays images, an upper module UM disposed on the display module DM, and a lower module LM disposed below the display module DM. The display module DM may constitute a part of the display device DD, and particularly, images may be generated from the display module DM. The display module DM may display images in response to an electrical signal, and transmit/receive information about an external input. The display module DM may be defined as an active region AA and a peripheral region NAA. The active region AA may be defined as a region in which images provided from the display module DM are displayed.

The peripheral region NAA is adjacent to the active region AA. In an embodiment, for example, the peripheral region NAA may surround the active region AA as shown in FIG. 3. However, this is illustrated as an example. The peripheral region NAA may be defined as having various shapes, and is not limited to any one embodiment. According to an embodiment, the active region AA of the display module DM may overlap at least a portion of the display region DA of FIG. 2A.

The display module DM may include a display panel DP and an input-sensing unit ISP. The display panel DP according to an embodiment of the invention may be a light-emitting display panel, and is not particularly limited. In an embodiment, for example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, for convenience of description, embodiments where the display panel DP is s an organic light-emitting display panel will be mainly described.

The display panel DP may be a flexible display panel. Accordingly, the display panel DP may be entirely rolled, or folded or unfolded with respect to the folding axis FX.

The input-sensing unit ISP may be directly disposed on the display panel DP. According to an embodiment of the invention, the input-sensing unit ISP may be formed on the display panel DP through a continuous process. In such an embodiment, where the input-sensing unit ISP is directly disposed on the display panel DP, an adhesive film is not disposed between the input-sensing unit ISP and the display panel DP. However, an embodiment of the invention is not limited thereto. In another embodiment, an adhesive film may be disposed between the input-sensing unit ISP and the display panel DP. In such an embodiment, the input-sensing unit ISP and the display panel DP may not be manufactured through a continuous process, but the input-sensing unit ISP may be manufactured through a separate process from the display panel DP and then fixed on an upper surface of the display panel DP by an adhesive film.

The display panel DP generates images, and the input-sensing unit ISP acquires coordinate information about a user's input (for example, a touch event).

The upper module UM may include a cover window WM disposed on the display module DM. The cover window WM may include an optically transparent insulating material. Accordingly, images generated from the display module DM pass through the cover window WM, and may thus be easily recognized by a user. The manufacturing of the cover window WM will be described in detail with reference to FIGS. 5A to 5C.

The upper module UM may further include one or more functional layers disposed between the display module DM and the cover window WM. In an embodiment of the invention, the functional layer may be an anti-reflection layer RPL which blocks reflection for external light, for example.

The anti-reflection layer RPL may effectively prevent elements constituting the display module DM from being viewed from the outside due to external light incident through a front surface of the display device DD. The anti-reflection layer RPL may include a retarder and a polarizer. The retarder may be a film type or a liquid crystal coating type, and may include a λ/2 retarder and/or a λ/4 retarder. The polarizer may also be a film type or a liquid crystal coating type. The film type may include a stretched synthetic resin film, and the liquid crystal coating type may include liquid crystals arranged in a predetermined arrangement. The retarder and polarizer may form one polarization film. The functional layer may further include a protective film disposed above or below the anti-reflection layer RPL.

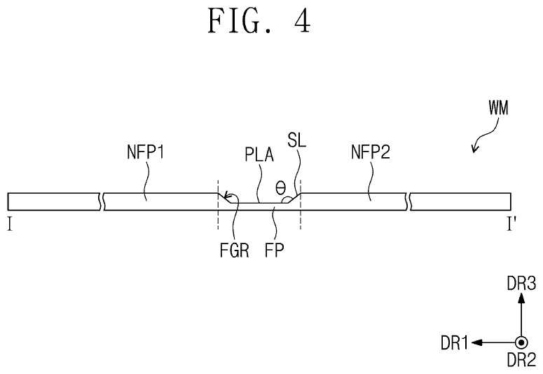

The lower module LM may include a support plate SP disposed on a rear surface of the display module DM and supporting the display module DM, and a protective film PF disposed between the display module DM and the support plate SP. The support plate SP may include support plates the number of which corresponds to the number of non-folding regions NFA1 and NFA2 (see FIG. 4). In an embodiment of the invention, for example, the support plate SP may include a first support plate SP1 and a second support plate SP2 located to be spaced apart from the first support plate SP1.

The first and second support plates SP1 and SP2 may be disposed to respectively correspond to first and second non-folding regions NFA1 and NFA2 (see FIG. 4). The first support plate SP1 is disposed to overlap the first non-folding region NFA1 (see FIG. 4), and the second support plate SP2 is disposed to overlap the second non-folding region NFA2 (see FIG. 4) of the display module DM. The first and second support plates SP1 and SP2 may each include a metal material or a plastic material.

In a state in which the electronic device ED is unfolded as illustrated in FIG. 2A, the first and second support plates SP1 and SP2 are spaced apart from each other in the first direction DR1. In a state in which the electronic device ED is folded with respect to the folding axis FX as illustrated in FIG. 2B, the first and second support plates SP1 and SP2 may be located to be spaced apart from each other in the third direction DR3.

The first and second support plates SP1 and SP2 may be spaced apart from each other to correspond to the folding region FA (see FIG. 4). The first and second support plates SP1 and SP2 may partially overlap the folding region FA (see FIG. 4). That is, a spacing distance between the first and second support plates SP1 and SP2 in the second direction DR2 may be smaller than a width of the folding region FA in the second direction DR2 (see FIG. 4).

Although not illustrated, the support plate SP may further include a connection module for connecting the first and second support plates SP1 and SP2. The connection module may include a hinge module or an articulated module.

In an embodiment, the support plate SP may include two support plates SP1 and SP2 as shown in FIG. 3, but an embodiment of the invention is not limited thereto. In an embodiment, where a plurality of folding axes FX are provided, the support plate SP may include a plurality of support plates separated with respect to the plurality of folding axes FX. Alternatively, the support plate SP may not be separated into the first and second support plates SP1 and SP2, but may be provided as an integrated shape. In such an embodiment, a bending portion may be provided to the support plate SP to correspond to the folding region FA (see FIG. 4). The bending portion may be provided with an opening formed by penetrating (or removing portions of) the support plate SP or may be provided with a groove recessed from one surface of the support plate SP.

The protective film PF may be disposed between the display module DM and the support plate SP. The protective film PF may be disposed below the display module DM, and may protect a rear surface of the display module DM. The protective film PF may include a synthetic resin film, for example, a polyimide film or a polyethyleneterephthalate film. However, this is presented as an example, and the protective film PF is not limited thereto.

The case HU may be coupled to the display device DD, e.g., to the cover window WM, and accommodate the display module DM and the lower module LM. In an embodiment, as shown in FIG. 3, the case HU may include first and second cases HU1 and HU2 separated from each other, but an embodiment of the invention is not limited thereto. Although not illustrated, the electronic device ED may further include a hinge structure for connecting the first and second cases HU1 and HU2.

FIG. 4 is a cross-sectional view of the cover window illustrated in FIG. 3.

Particularly, FIG. 4 is a cross-sectional view of a cover window WM taken along line I-I′ illustrated in FIG. 3.

Referring to FIG. 4, an embodiment of the cover window WM may include a first non-folding part NFP1, a second non-folding part NFP2, and a folding part FP. The folding part FP may be disposed between the first non-folding part NFP1 and the second non-folding part NFP2. The first non-folding part NFP1, the folding part FP, and the second non-folding part NFP2 may be arranged in the first direction DR1.

The first non-folding part NFP1 may overlap (or correspond to) the first non-folding region NFA1 of FIG. 2A. The second non-folding part NFP2 may overlap (or correspond to) the second non-folding region NFA2 of FIG. 2A. The folding part FP may overlap (or correspond to) the folding region FA of FIG. 2A.

A folding groove FGR may be defined on an upper surface of the folding part FP. The folding groove FGR may extend from the upper surface of the folding part FP toward a lower surface of the folding part FP. In an embodiment, for example, the folding groove FGR may have a shape partially corresponding to a trapezoid. However, a shape of the folding groove FGR is not limited thereto.

The thickness of the folding part FP may be smaller than the thickness of the first non-folding part NFP1 and the thickness of the second non-folding part NFP2. The height of the upper surface of the folding part FP with respect to a lower surface thereof may be smaller than the height of an upper surface of the first non-folding part NFP1 with respect to the lower surface thereof and the height of an upper surface of the second non-folding part NFP2 with respect to the lower surface thereof.

Since the thickness of the folding part FP is smaller than the thickness of the first non-folding part NFP1 and the thickness of the second non-folding part NFP2, when the display device DD (see FIG. 3) is folded, the folding part FP of the cover window WM may be easily folded.

As the thickness of the first non-folding part NFP1 and the thickness of the second non-folding part NFP2 are greater than the thickness of the folding part FP, the first non-folding part NFP1 and the second non-folding part NFP2 may have rigidity higher than that of the folding part FP.

An inner side surface of the folding part FP, defining the folding groove FGR, may include a flat portion PLA and a plurality of inclined portions SL. Although not illustrated, the flat portion PLA may be parallel to a plane defined by the first direction DR1 and the second direction DR2.

The inclined portions SL may be disposed between the flat portion PLA and the first non-folding part NFP1 and between the flat portion PLA and the second non-folding part NFP2. The inclined portions SL may extend from both opposing sides of the flat portion PLA, which are opposed to each other in the first direction DR1 and extend up to the first non-folding part NFP1 and the second non-folding part NFP2. One upper surface of the inclined portions SL may connect the upper surface of the first non-folding part NFP1 and the upper surface of the flat portion PLA. The other upper surface of the inclined portions SL may connect the upper surface of the second non-folding part NFP2 and the upper surface of the flat portion PLA.

An angle formed between the upper surfaces of the inclined portions SL and the upper surface of the flat portion PLA may be defined as a first angle θ. When viewed from the second direction DR2, the first angle θ may be an obtuse angle. A size of the first angle θ may be inversely proportional to inclinations of the upper surfaces of the inclined portions SL.

Whether boundaries between the folding part FP and the first and second non-folding parts NFP1 and NFP2 are viewed from the outside (or visible to a user) may be determined according to a size of the first angle θ. As a size of the first angle θ increases, the boundaries between the folding part FP and the first and second non-folding parts NFP1 and NFP2 may be invisible. As inclinations of the inclined portions SL decrease, the boundaries between the folding part FP and the first and second non-folding parts NFP1 and NFP2 may be invisible. In an embodiment, for example, the first angle θ may be in a range of about 170° to about 179.5°.

However, an embodiment of the invention is not limited thereto, and a size of the first angle θ may vary according to thicknesses of the first and second non-folding parts NFP1 and NFP2, and the folding part FP, or to a width of the folding part FP in the first direction DR1.

The cover window WM may be manufactured by using the cover window etching device WEA illustrated in FIG. 1. An embodiment of a method of manufacturing the cover window WM will be described later in detail.

FIGS. 5A to 5C are cross-sectional views for describing an embodiment of a method for etching the cover window illustrated in FIG. 4.

Particularly, FIGS. 5A to 5C are cross-sectional views when viewed from the second direction DR2.

Among components illustrated in FIGS. 5A to 5C, the description of components which are described with reference to the above-described drawings and are identical or similar to the described components will be omitted or simplified.

Referring to FIG. 5A, an embodiment of a method for etching the cover window WM for the electronic device ED (see FIG. 2A) may include a process of disposing a preliminary cover window IWM on a stage STG. The preliminary cover window IWM may be fixed onto an upper surface of the stage STG from the outside of a housing HS, and then be conveyed into an accommodation groove AGR via conveying parts WH.

The preliminary cover window IWM may include first and second non-folding parts NFP1 and NFP2, and a preliminary folding part IFP. The first and second non-folding parts NFP1 and NFP2 of the preliminary cover window IWM may be the same as the first and second non-folding parts NFP1 and NFP2 (see FIG. 4) of the cover window WM (see FIG. 4). The preliminary folding part IFP may correspond to the folding part FP (see FIG. 4) before being etched.

The preliminary folding part IFP may include a preliminary flat portion IPL and a plurality of preliminary inclined portions ISL. The preliminary flat portion IPL may correspond to the flat portion PLA (see FIG. 4) before being etched, and the preliminary inclined portions ISL may correspond to the inclined portions SL (see FIG. 4) before being etched.

The preliminary cover window IWM may be disposed between the stage STG and plates PLT inside the accommodation groove AGR. The preliminary cover window IWM may be disposed below the plates PLT.

The plates PLT may be spaced apart from each other on the preliminary cover window IWM in the first direction DR1. The plates PLT may overlap the preliminary inclined portions ISL. The plates PLT may not overlap the preliminary flat portion IPL. The preliminary flat portion IPL may be exposed from the plates PLT to the outside.

Referring to FIG. 5B, when the preliminary cover window IWM is disposed inside the accommodation groove AGR, a process of spraying an etchant EL by using a nozzle NZ may be performed. The nozzle NZ disposed above the plates PLT may spray the etchant EL toward the preliminary cover window IWM. In an embodiment, for example, the etchant may be hydrogen fluoride (HF).

The preliminary flat portion IPL exposed from the plates PLT to the outside may be etched by the etchant EL. The preliminary inclined portions ISL, the first non-folding part NFP1, and the second non-folding part NFP2, which are covered by the plates PLT, may not be etched by the etchant EL.

Referring to FIGS. 4, 5B and 5C, when the nozzle NZ sprays the etchant EL, driving parts DU may move in the first direction DR1 toward an opening OP. When the driving parts DU move in the first direction DR1, the plates PLT may move in the first direction DR1. In an embodiment, for example, the plates PLT may move at a constant speed. However, an embodiment of the invention is not limited thereto, and a moving speed of the plates PLT may be controlled based on the etching amount of the preliminary folding part IFP.

A distance between the plates PLT spaced apart from each other in the first direction DR1 may increase. An area of the preliminary folding part IFP exposed from the plates PLT to the outside may increase. The preliminary inclined portions ISL may be exposed from the plates PLT to the outside. Accordingly, the preliminary inclined portions ISL may be etched by the etchant EL.

The time for which the etchant EL is sprayed on the preliminary flat portion IPL may be longer than the time for which the etchant EL is sprayed on the preliminary inclined portions ISL. Accordingly, the etching amount of the preliminary flat portion IPL may be greater than the etching amount of the preliminary inclined portions ISL.

The time for which the etchant EL is sprayed on a portion of the preliminary inclined portions ISL, which is adjacent to the preliminary flat portion IPL, may be longer than the time for which the etchant EL is sprayed on a portion of the preliminary inclined portions ISL, which is adjacent to the first and second non-folding parts NFP1 and NFP2. Accordingly, the preliminary inclined portions ISL are etched in a way such that the upper surfaces of the inclined portions SL may have inclinations as illustrated in FIG. 4.

The plates PLT may cover the first and second non-folding parts NFP1 and NFP2 to effectively prevent the first and second non-folding parts NFP1 and NFP2 from being etched. The preliminary cover window IWM is etched by the etchant EL, and then the cover window WM of FIG. 4 may be manufactured.

Conventionally, a mask including titanium (Ti) may be disposed on the first and second non-folding parts NFP1 and NFP2 to prevent the first and second non-folding parts NFP1 and NFP2 from being etched. Accordingly, a conventional method for etching the cover window WM may include processes of disposing the mask on the first and second non-folding parts NFP1 and NFP2 and removing the mask from the first and second non-folding parts NFP1 and NFP2. Therefore, process steps may be increased.

In this case, during the process of removing the mask from the first and second non-folding parts NFP1 and NFP2, the first and second non-folding parts NFP1 and NFP2 may be damaged. Accordingly, defects in the cover window WM may occur.

Furthermore, as a thickness of the mask increases, a size of the first angle θ may decrease. The upper surfaces of the inclined portions SL may have increased inclinations. Accordingly, the boundaries between the folding part FP and the first and second non-folding parts NFP1 and NFP2 may be visible from the outside.

In the cover window etching device WEA for manufacturing the electronic device according to an embodiment of the invention, the plates PLT may effectively prevent the first and second non-folding parts NFP1 and NFP2 from being etched. Accordingly, the processes of disposing the mask on the first and second non-folding parts NFP1 and NFP2 and removing the mask from the first and second non-folding parts NFP1 and NFP2 may be omitted such that the cover window WM may be easily or efficiently etched, that is, the process of etching the cover window WM may be simplified.

In such an embodiment, damages in the first and second non-folding parts NFP1 and NFP2 that may occur during the process of removing the mask from the first and second non-folding parts NFP1 and NFP2 may be effectively prevented. Accordingly, defect occurrence in the cover window WM may be prevented or reduced.

In such an embodiment, since the mask process is omitted, it may be easy to adjust a size of the first angle θ and inclinations of the upper surfaces of the inclined portions SL. Therefore, boundaries between the folding part FP and the first and second non-folding parts NFP1 and NFP2 may be effectively prevented from being visible.

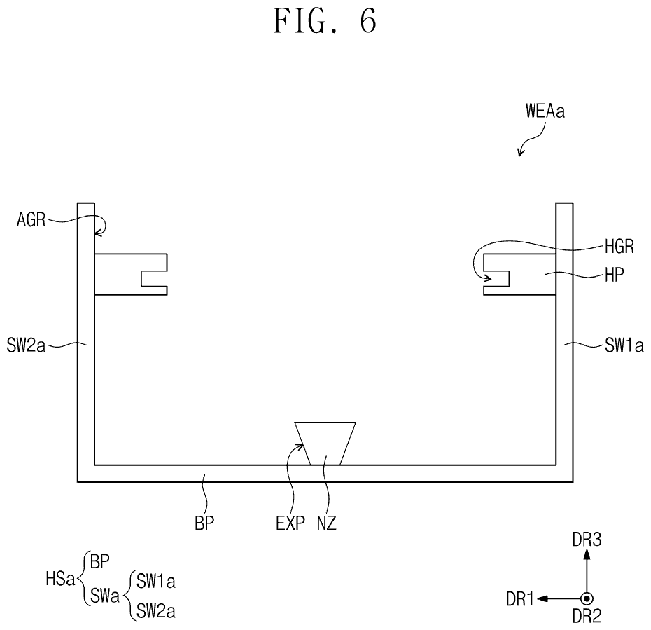

FIG. 6 is a cross-sectional view of a cover window etching device for manufacturing an electronic device according to an embodiment of the invention.

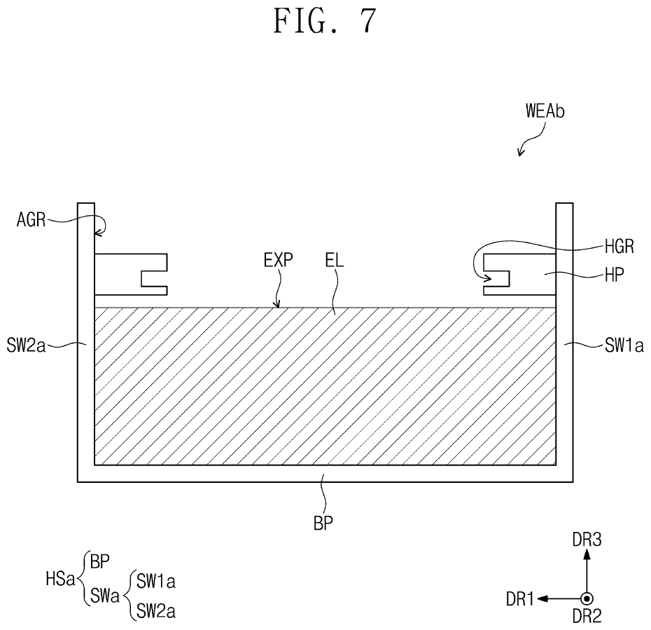

FIG. 7 is a cross-sectional view of a cover window etching device for manufacturing an electronic device according to an embodiment of the invention.

Particularly, FIGS. 6 and 7 are cross-sectional views of cover window etching devices WEAa and WEAb for manufacturing an electronic device when viewed from the second direction DR2.

Referring to FIG. 6, an embodiment of the cover window etching device WEAa for manufacturing the electronic device may include a housing HSa, a plurality of holding parts HP, and a source part EXP. The housing HSa may define an accommodation groove AGR that accommodates the holding parts HP and the source part EXP.

The housing HSa may include a floor portion BP, and side wall portions SWa. Since the floor portion BP is the substantially same as the floor portion BP of FIG. 1, any repetitive detailed description of the floor portion BP will be omitted. The side wall portions SWa may extend in the third direction DR3 from both sides, of the floor portion BP, opposed to each other in the first direction DR1. The side wall portions SWa may be spaced apart from each other in the first direction DR1.

The side wall portions SWa may include a first side wall portion SW1a and a second side wall portion SW2a. When viewed from the second direction DR2, the first side wall portion SW1a may be adjacent to the right side of the floor portion BP. The second side wall portion SW2a may be adjacent to the left side of the floor portion BP. The housing HSa of FIG. 6 may be substantially identical or similar to the housing HS of FIG. 1 except for the gate GAT (see FIG. 1), and hereinafter, any repetitive detailed description of the housing HSa will be omitted.

The holding parts HP may be disposed on an inner side surface of the first side wall portion SW1a and an inner side surface of the second side wall portion SW2a, and the inner side surfaces face each other in the first direction DR1. The holding parts HP may be spaced apart from each other in the first direction DR1. The holding parts HP may face each other in the first direction DR1.

The holding parts HP may reciprocate in the first direction DR1. A distance between the holding parts HP in the first direction DR1 may vary. The reciprocal movement of the holding parts HP in the first direction DR1 will be described below in detail.

Holding grooves HGR may be defined on facing sides of the holding parts HP facing each other among opposing sides of the holding parts HP, which are opposed to each other in the first direction DR1. The holding grooves HGR may extend in the first direction DR1 from the facing sides of the holding parts HP toward outer sides of the holding parts HP.

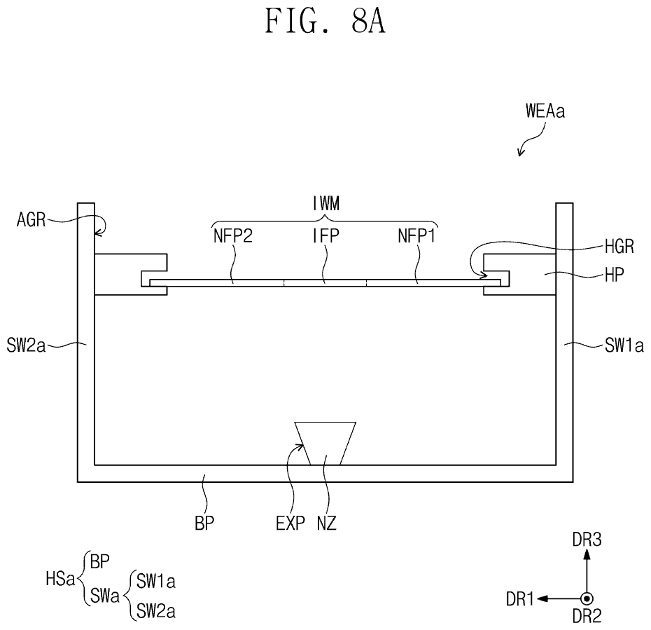

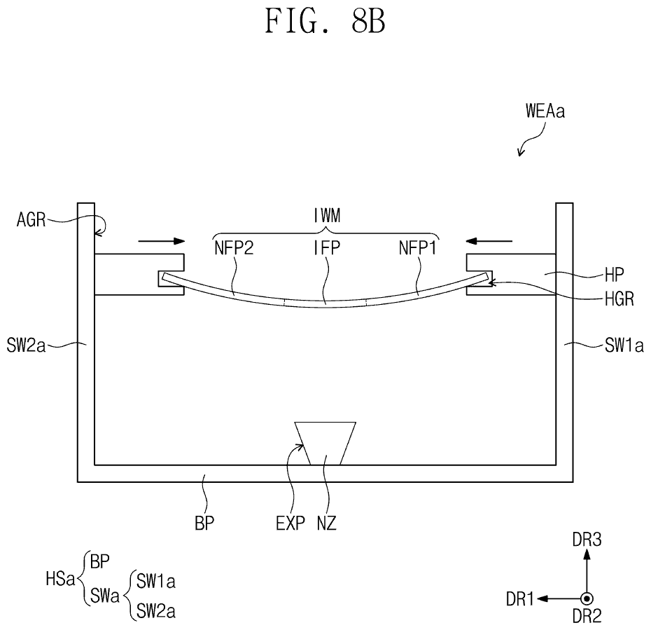

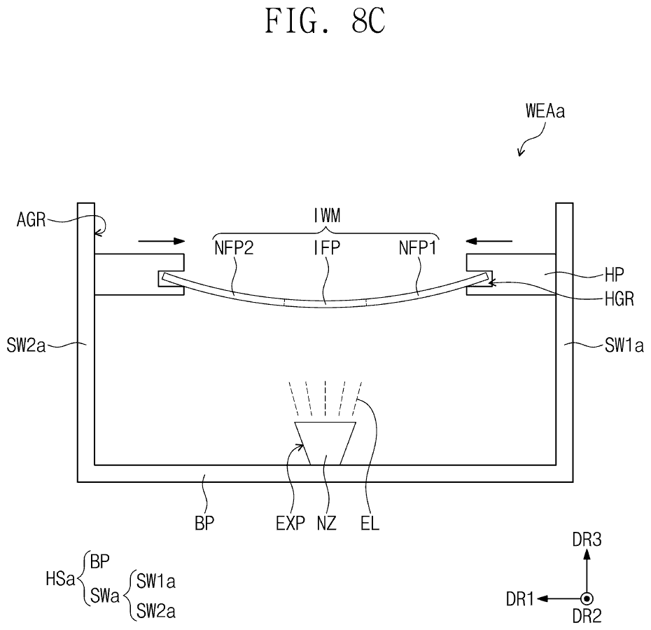

The source part EXP may be disposed inside the accommodation groove AGR. The source part EXP may be disposed below the holding parts HP. The source part EXP may include a nozzle NZ. The nozzle NZ may be disposed above an upper surface of the floor portion BP. The nozzle NZ may spray an etchant EL (see FIG. 8C) upward. However, this is presented as an example, and in another embodiment, the source part EXP may include the etchant EL accommodated inside the accommodation groove AGR as illustrated in FIG. 7.

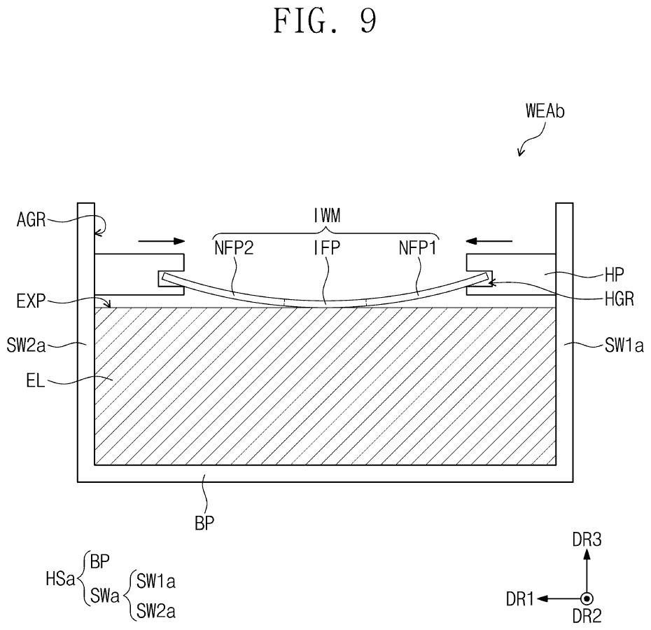

FIGS. 8A to 8C are views describing a method for etching a cover window by using the cover window etching device for manufacturing the electronic device illustrated in FIG. 6. FIG. 9 is a view describing a method for etching a cover window by using the cover window etching device for manufacturing the electronic device illustrated in FIG. 7.

Particularly, FIGS. 8A to 9 are cross-sectional views of cover window etching devices WEAa and WEAb for manufacturing an electronic device when viewed from the second direction DR2.

Among components illustrated in FIGS. 8A to 9, the description of components which are described with reference to the above-described drawings and are identical or similar to the described components will be omitted or simplified.

Referring to FIG. 8A, an embodiment of a method for etching the cover window WM (see FIG. 4) for the electronic device ED (see FIG. 2A) may include a process of disposing a preliminary cover window IWM inside an accommodation groove AGR. The preliminary cover window IWM may be disposed between holding parts HP. The preliminary cover window IWM may be disposed inside holding grooves HGR. Both opposing sides of the preliminary cover window IWM, which are opposed to each other in the first direction DR1, may be disposed inside the holding grooves HGR, respectively.

Referring to FIG. 8B, when the preliminary cover window IWM is disposed inside the holding grooves HGR, the holding parts HP may move in the first direction DR1. As the holding parts HP move, a distance between the holding parts HP in the first direction DR1 may decrease.

As the distance between the holding parts HP decreases, the preliminary cover window IWM disposed between the holding parts HP may be bent. An upper surface of the preliminary cover window IWM may have a curved surface which is concave downward. A lower surface of the preliminary cover window IWM may have a curved surface which is convex downward. The height of a lower surface (or a lowermost point) of the preliminary folding part IFP with respect to the floor portion BP may be smaller than the height of a lower surface (or a lowermost point) of the first non-folding part NFP1 with respect to the floor portion BP and the height of a lower surface (or a lowermost point) of the second non-folding part NFP2 with respect to the floor portion BP.

Referring to FIG. 8C, the nozzle NZ may spray the etchant EL toward the preliminary cover window IWM. The etchant EL may be sprayed toward a portion the height of which is lower than that of a peripheral portion in the lower surface of the preliminary cover window IWM. The etchant EL may be sprayed toward the preliminary folding part IFP.

When an etching process is performed by using the etching device WEAa on the cover window WM (see FIG. 4) for the electronic device ED (see FIG. 2A) according to an embodiment of the invention, the preliminary cover window IWM may be bent. Accordingly, the preliminary folding part IFP gets closer to the nozzle NZ than the first non-folding part NFP1 and the second non-folding part NFP2, and thus it may be easy to spray the etchant EL toward the preliminary folding part IFP. In such an embodiment, since the lower surface of the preliminary cover window IWM is deformed to be convex downward, even when the etchant EL is provided on the lower surfaces of the first and second non-folding parts NFP1 and NFP2, the etchant EL may flow toward the preliminary folding part IFP. Therefore, an etching process for manufacturing the cover window WM (see FIG. 4) may be facilitated.

In such an embodiment, a process of separately providing and removing a mask to prevent the first and second non-folding parts NFP1 and NFP2 from being etched may be omitted, and thus the etching process for manufacturing the cover window WM (see FIG. 4) may be simplified.

Referring to FIG. 9, in an embodiment of a method for etching the cover window WM (see FIG. 4) for the electronic device ED (see FIG. 2A), a preliminary folding part IFP in a bent state may be immersed in an etchant EL accommodated inside an accommodation groove AGR. First and second non-folding parts NFP1 and NFP2 may not be immersed in the etchant EL. Therefore, the etching process for manufacturing the cover window WM (see FIG. 4) may be facilitated.

According to an embodiment of the invention, when an etchant is sprayed from a nozzle toward a preliminary cover window, plates may move away from each other. Accordingly, a preliminary folding part of the preliminary cover window, which is exposed from plates to the outside, may be etched by the etchant, and non-folding parts may be covered by the plates and not be etched. Therefore, a cover window may be easily etched.

According to an embodiment of the invention, a distance between the plates may gradually increase. Accordingly, preliminary inclined portions of a preliminary folding part may have a shorter contact time with an etchant than a preliminary flat portion of the preliminary folding part, and the etching amount of the preliminary inclined portions may be smaller than the etching amount of the preliminary flat portion. Therefore, it is possible to effectively prevent boundaries between the non-folding parts and the flat portions from being visible.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A cover window etching device for manufacturing an electronic device, the cover window etching device comprising:
a stage on which a preliminary cover window is disposed;
a plurality of plates disposed above the stage; and
a nozzle disposed above the plates, wherein the nozzle sprays an etchant toward the preliminary cover window,
wherein the plates reciprocate in a first direction.

2. The cover window etching device of claim 1, wherein the plates are spaced apart from each other in the first direction.

3. The cover window etching device of claim 2, wherein when the nozzle sprays the etchant, the plates move.

4. The cover window etching device of claim 3, wherein when the nozzle sprays the etchant, a distance between the plates in the first direction increases.

5. The cover window etching device of claim 4, wherein when a distance between the plates in the first direction increases, an area of the preliminary cover window exposed from the plates to an outside increases.

6. The cover window etching device of claim 4, wherein a moving speed of each of the plates is constant.

7. The cover window etching device of claim 1, further comprising a housing defining an accommodation groove in which the stage and the plates are accommodated.

8. The cover window etching device of claim 7, further comprising a plurality of driving parts which are disposed in openings defined on inner side surfaces of the housing defining the accommodation groove and are connected to facing sides of the plates,
wherein the facing sides of the plates are defined as sides facing each other in the first direction.

9. The cover window etching device of claim 8, wherein when the driving parts reciprocate into or out of the openings in the first direction, the plates reciprocate in the first direction.

10. A cover window etching method for manufacturing an electronic device, the method comprising:
disposing a preliminary cover window on a stage;
moving the stage to be disposed below a plurality of plates spaced apart from each other in a first direction inside an accommodation groove defined by a housing; and
etching the preliminary cover window by spraying an etchant toward the preliminary cover window by using a nozzle disposed above the plates,
wherein when the nozzle sprays the etchant, the plates move in the first direction.

11. The method of claim 10, wherein when the nozzle sprays the etchant, a distance between the plates in the first direction increases.

12. The method of claim 11, wherein when a distance between the plates in the first direction increases, an area of the preliminary cover window exposed from the plates to an outside increases.

13. The method of claim 10, wherein a moving speed of each of the plates is constant.

14. The method of claim 13, further comprising a plurality of driving parts which are disposed in openings defined on inner side surfaces of the housing defining the accommodation groove and are connected to facing sides of the plates,
wherein the facing sides of the plates are defined as sides facing each other in the first direction.

15. A cover window etching device for manufacturing an electronic device, the cover window etching device comprising:
a plurality of holding parts spaced apart from each other in a first direction, wherein the holding parts support a preliminary cover window;
a source part disposed below the holding parts; and
a housing which accommodates the holding parts and the source part,
wherein the holding parts reciprocate in the first direction.

16. The cover window etching device of claim 15, wherein the preliminary cover window is disposed in holding grooves defined on facing sides of the holding parts facing each other in the first direction.

17. The cover window etching device of claim 16, wherein the holding parts move in the first direction, and a distance between the holding parts in the first direction decreases.

18. The cover window etching device of claim 17, wherein when a distance between the holding parts in the first direction decreases, a lower surface of the preliminary cover window is deformed into a curved surface which is convex downward.

19. The cover window etching device of claim 18, wherein the source part comprises a nozzle which sprays an etchant toward the preliminary cover window.

20. The cover window etching device of claim 18, wherein the source part comprises an etchant accommodated inside an accommodation groove defined by the housing, and
a portion of the window having a lower height than a peripheral portion is immersed in the etchant.
